(19) United States
(12) Patent Application Publication
(10) Pub. No.: US 2011/0180131 A1
(43) Pub. Date: Jul. 28, 2011

(54) METHOD FOR ATTACHING CONTACTS TO A SOLAR CELL WITHOUT CELL EFFICIENCY LOSS

(75) Inventors: James W. MULLIN, North Andover, MA (US); Russell J. Low, Rowley, MA (US)

(73) Assignee: VARIAN SEMICONDUCTOR EQUIPMENT ASSOCIATES, INC., Gloucester, MA (US)

(21) Appl. No.: 12/694,750

(22) Filed: Jan. 27, 2010

(51) Int. Cl. H01L 31/0224; H01L 31/18

(52) U.S. Cl. 136/256; 438/98; 257/E21.158

(57) ABSTRACT

A method of implanting a substrate and the resulting apparatus are disclosed. The substrate, which may be a solar cell, is implanted with a p-type dopant. The p-type dopant may be, for example, boron, aluminum, gallium, or indium. Contacts are formed over the p-type region that is formed by the implant. An aluminum layer is formed around these contacts such that a surface of the contacts is still exposed. The implant may be a blanket implant across the entire surface of the substrate or a selective implant into a portion of the substrate. The substrate may be either n-type or p-type.

### FIELD

This invention relates to improving solar cell performance and, more particularly, to attaching contacts to a solar cell substrate.

### BACKGROUND

Solar cells are strung together in modules by soldering the solar cells together. Many solar cells designs, however, include an aluminum layer on the non-illuminated surface. Besides acting as a reflector or passivator, aluminum is a p-type dopant. For a p-type substrate, the aluminum layer acts as a doped p+ layer that is referred to as a back surface field (BSF). For an n-type substrate, the aluminum layer likewise acts as a doped p+ layer, but is instead referred to as an emitter. The aluminum layer also may serve as an electrical contact. Aluminum, however, is difficult to solder. Contacts, which in one instance are composed of silver, may be used to string multiple solar cells together, but it is difficult to bond silver to aluminum. Thus, to solder these solar cells together, contacts need to be attached to the silicon of the solar cell substrate rather than the aluminum.

In one instance, adding contacts to the non-illuminated surface of the solar cell substrate may shunt the solar cell. This shunting may divert a fraction of the current generated by the solar cell. FIG. 1 is a cross-sectional view of shunting in a first embodiment of a solar cell. The solar cell 200 includes a substrate 100 with a non-illuminated surface 202. The non-illuminated surface 202 includes an aluminum layer 101 with contacts 102. The substrate 100 also has an illuminated surface 203 that is impinged by light. The illuminated surface has contacts 103 and an anti-reflective coating (ARC) 104, which may be silicon nitride. In this particular embodiment, the substrate 100 in the solar cell 200 may be n-type. Electrons shunt from the contacts 103 to the contacts 102 as illustrated by arrows 201. If the substrate 100 is n-type, the aluminum layer 101 serves as a p+ region and causes or influences the electrons to stay in the substrate 100 or to flow to the contacts 102. The contacts 102 do not repel the electrons and the shunt becomes a current path in the solar cell 200 circuit. This limits operation of the solar cell 200 because the solar cell 200 effectively lacks a p-n junction and may begin acting like a resistor.

Other solar cells use a p-type substrate. For a p-type substrate, attaching silver directly to silicon breaks any BSF because the aluminum will form an aluminum-silicon eutectic and, consequently, a BSF under the aluminum layer. Interrupting the aluminum layer to attach contacts likewise interrupts this BSF. Attaching the contacts to the non-illuminated surface of the solar cell substrate in this instance may reduce the efficiency of the solar cell by approximately 0.2% due to increased carrier recombination. Accordingly, there is a need in the art for an improved method of attaching contacts to a solar cell substrate and, more particularly, a method of attaching contacts that are not p-type to a solar cell substrate.

### SUMMARY

According to a first aspect of the invention, a method to process a substrate is disclosed. The method comprises implanting a first surface of a p-type substrate with a p-type dopant thereby forming a p-type region. A plurality of contacts is formed on the first surface of the p-type substrate. Each of the plurality of contacts has a contact surface opposite the first surface of the p-type substrate. An aluminum layer is formed on the first surface of the p-type substrate. The aluminum layer is disposed around the plurality of contacts such that the contact surface of each of the plurality of contacts is exposed. The plurality of contacts is disposed on the p-type region.

According to a second aspect of the invention, a method to process a substrate is disclosed. The method comprises implanting a p-type dopant into a first surface of an n-type substrate thereby forming a p-type emitter. A plurality of contacts is formed on the first surface of the n-type substrate. Each of the plurality of contacts has a contact surface opposite the first surface of the n-type substrate. An aluminum layer is formed on the first surface of the n-type substrate. The aluminum layer is disposed around the plurality of contacts such that the contact surface of each of the plurality of contacts is exposed. The plurality of contacts is disposed on the p-type emitter.

According to a third aspect of the invention, a solar cell is disclosed. The solar cell comprises a substrate having an illuminated surface and a non-illuminated surface. Light impinges the illuminated surface. A p-type region in the substrate is proximate the non-illuminated surface. A plurality of contacts is disposed on the non-illuminated surface of the substrate. Each of the plurality of contacts has a first surface and a second surface. The second surface is disposed on the p-type region of the substrate. An aluminum layer is disposed on the non-illuminated surface of the substrate. The aluminum layer is disposed around the plurality of contacts such that the first surface of each of the plurality of contacts is exposed.

### BRIEF DESCRIPTION OF THE DRAWINGS

For a better understanding of the present disclosure, reference is made to the accompanying drawings, which are incorporated herein by reference and in which:

FIG. 1 is a cross-sectional view of shunting in a first embodiment of a solar cell;

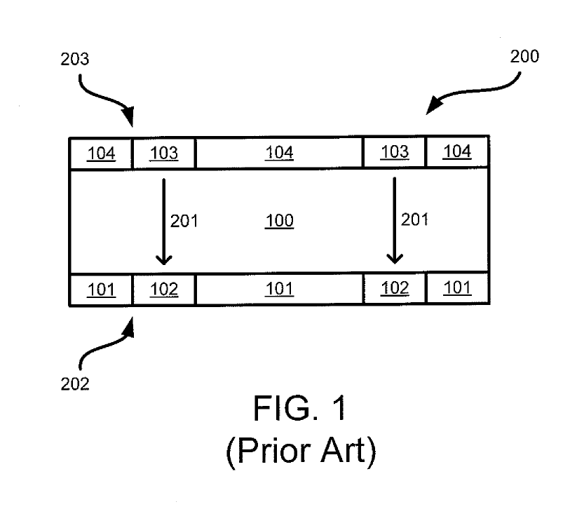

FIGS. 2A-D illustrate a first process of fabricating a solar cell;

FIG. 3 is a cross-sectional view of a first embodiment of a solar cell with an aluminum eutectic;

FIGS. 4A-D illustrate a second process of fabricating a solar cell;

FIG. 5 is a cross-sectional diagram of selective implantation;

FIGS. 6A-D illustrate a third process of fabricating a solar cell;

FIGS. 7A-D illustrate a fourth process of fabricating a solar cell;

FIGS. 8A-D illustrate a fifth process of fabricating a solar cell; and

FIG. 9 is a cross-sectional view of a second embodiment of a solar cell with an aluminum eutectic.

### DETAILED DESCRIPTION

The methods and apparatus are described herein in connection with a solar cell. However, the methods and apparatus can be used with other systems and processes involved in semiconductor manufacturing, light-sensitive devices, or other workpieces that use contacts. The apparatus and methods described herein also may be applied to other solar cells designs known to those skilled in the art besides those illustrated. A beamline ion implanter, plasma doping ion implanter, plasma flood ion implanter, plasma immersion ion implanter, or other implant systems may be used for the ion implantation steps described herein. Screen printing, ink jet printing, or other methods known to those skilled in the art may be used to form the aluminum layer. Thus, the invention is not limited to the specific embodiments described below.

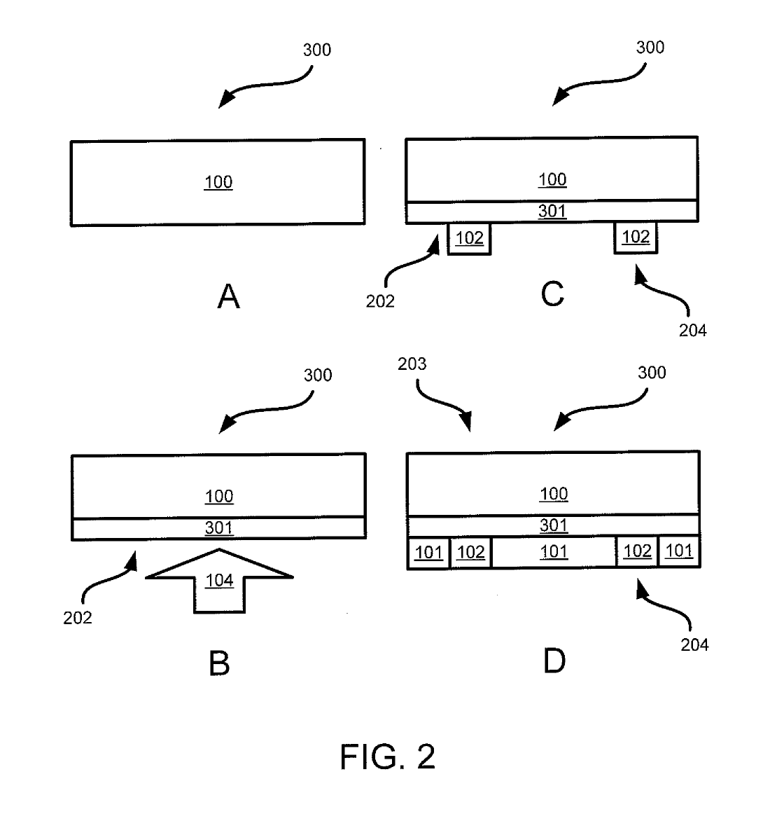

FIGS. 2A-D illustrate a first process of fabricating a solar cell. The substrate 100 of the solar cell 300 in FIG. 2A may be either p-type or n-type. In FIG. 2B, a blanket ion implant of a p-type dopant 104, such as boron, aluminum, gallium, or indium, into the substrate 100 is performed. This implant covers the entire non-illuminated surface 202 of the solar cell 300 and forms the p-type region 301 in the substrate 100. The depth of the p-type region 301 is related to the implant energy of the p-type dopant 104. Higher implant energy means a higher implant depth. The concentration in the p-type region 301 is related to the dose of the p-type dopant 104. A higher dose of p-type dopant 104 increases the concentration in the p-type region 301.

In FIG. 2C, contacts 102 are disposed on the non-illuminated surface 202 of the solar cell 300. The contacts 102 may be silver, TiPdAg, copper, a metal, an epoxy, or some other conductive element or compound. In one instance, these contacts 102 are applied using a screen printing process and are then dried. The contacts 102 each have a contact surface 204 opposite of the non-illuminated surface 202. In FIG. 2D, an aluminum layer 101 is disposed on the non-illuminated surface 202 of the solar cell 300. The aluminum layer 101 may be formed by screen printing, physical vapor deposition (PVD), or sputter/evaporation followed by a drying step. The contact surface 204 of each contact 102 is still exposed because the aluminum layer 101 does not cover the contacts 102. Instead, the aluminum layer 101 fills in between the contacts 102.

The solar cell 300 may be processed in a furnace, such as after the implantation of a p-type dopant 104 in FIG. 2B or at other times. In one particular embodiment, the contacts 102 and aluminum layer 101 are co-fired after both have been placed on the solar cell 300. The contacts 102 and aluminum layer 101 also may be co-fired with any contacts on the illuminated surface 203. If the solar cell 300 has other ion implant steps performed, such as forming a front selective emitter under contacts on the illuminated surface 203, doping the illuminated surface 203 of the solar cell 300, or forming front surface fields on the illuminated surface 203 for n-type back junction designs, then these implant steps are likewise activated. In an alternate embodiment, the aluminum layer 101 is disposed on the non-illuminated surface 202 of the solar cell 300 prior to the contacts 102 being disposed on the non-illuminated surface 202 of the solar cell 300. In yet another alternate embodiment, the p-type dopant 104 is implanted through either the aluminum layer 101 or contacts 102. Thus, the contacts 102 or aluminum layer 101 may be disposed on the solar cell 300 prior to implantation.

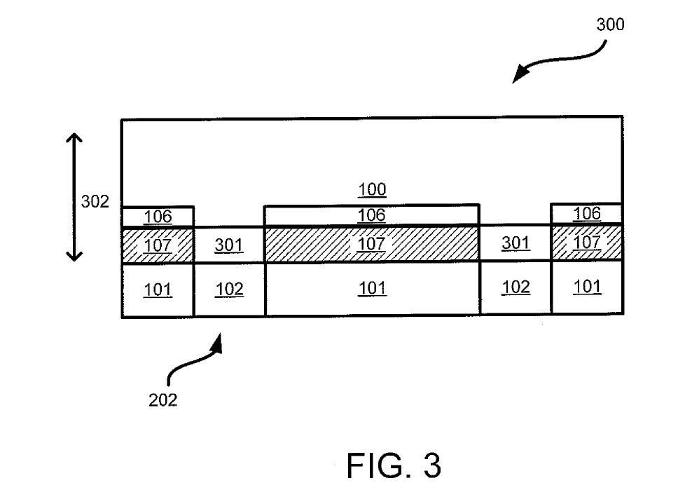

FIG. 3 is a cross-sectional view of a first embodiment of a solar cell with an aluminum eutectic. The eutectic is a mixture of two or more solids with proportions such that the melting point of the mixture is at a temperature where the solids crystallize simultaneously from a molten liquid solution. This eutectic may be a metal alloy in one instance. A silicon-aluminum eutectic will act as a p+ region.

The solar cell 300 had a blanket implant of p-type dopant as illustrated in FIG. 2B. After activation of the p-type dopant and aluminum, the p-type region 301 may only be, for example, approximately 1 μm or less in thickness or height, which is represented by the direction 302 in FIG. 3. In contrast, the silicon-aluminum eutectic that occurs after firing of the aluminum layer 101 may be over approximately 5 μm in thickness or height in one instance. Thus, the p+ dopant under the contacts 102 is the p-type region 301 but the p+ dopant under the aluminum layer 101 may be a first region 107 of aluminum and the p-type dopant 104 and a second region 106 of aluminum. In an alternate embodiment, there is less segregation than illustrated in FIG. 3 of the p-type dopant and aluminum so only a first region 107 is formed under the aluminum layer 101.

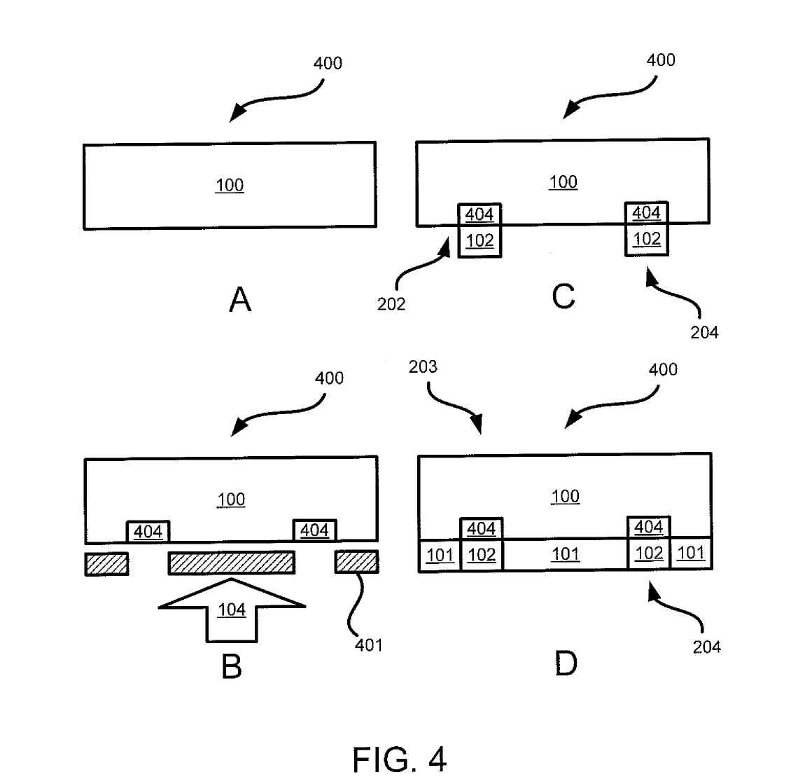

FIGS. 4A-D illustrate a second process of fabricating a solar cell. The substrate 100 of the solar cell 400 in FIG. 4A may be either n-type or p-type. Instead of the blanket ion implant of p-type dopant 104 as seen in FIG. 2B, in FIG. 4B a selective implant of p-type dopant 104 is performed. The selective implant uses a mask 401 and forms the p-type regions 404. The p-type regions 404 also may be referred to as p-type sections. These p-type regions 404 are interrupted and do not cover the entire non-illuminated surface 202 of the substrate 100.

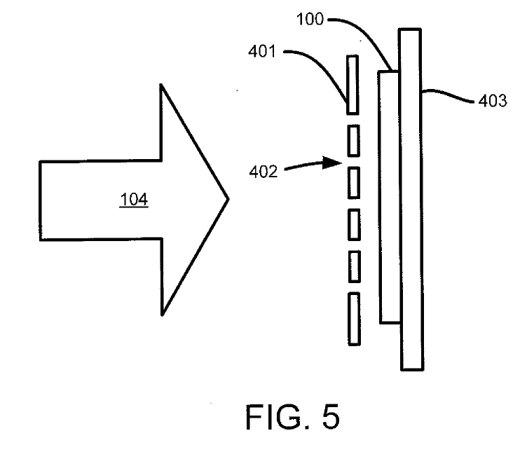

Turning to FIG. 5, a cross-sectional diagram of selective implantation is illustrated. When a specific pattern of ion implantation in a substrate 100 is desired, a mask 401 may be used. This mask 401 may be a shadow or proximity mask. The mask 401 is placed in front of a substrate 100 in the path of a p-type dopant 104 during implantation. The substrate 100 may be placed on a platen 403, which may use electrostatic or physical force to retain the substrate 100. The mask 401 has apertures 402 that correspond to the desired pattern of ion implantation in the substrate 100. The apertures 402 may be stripes, dots, or other shapes. While the mask 401 is illustrated, photoresist, other hard masks, or other methods known to those skilled in the art likewise may be used in an alternate embodiment.

Turning back to FIG. 4C, the contacts 102 are applied primarily to the p-type regions 404 formed using the mask 401 on the non-illuminated surface 202. The application of the contacts 102 is aligned to the p-type regions 404. In FIG. 4D, an aluminum layer 101 is disposed on the non-illuminated surface 202 of the solar cell 400. The aluminum layer 101 may be formed by screen printing, PVD, or sputter/evaporation followed by a drying step. The aluminum layer 101 is primarily applied to the substrate 100 rather than the portion of the non-illuminated surface 202 that includes the p-type regions 404. The contact surface 204 of each contact 102 is still exposed because the aluminum layer 101 does not cover the contacts 102. Instead, the aluminum layer 101 fills in between the contacts 102.

The solar cell 400 may be processed in a furnace, such as after the implantation of a p-type dopant 104 in FIG. 4B or at other times. If the solar cell 400 has other ion implant steps performed, such as forming a front selective emitter under contacts on the illuminated surface 203, doping the illuminated surface 203 of the solar cell 400, or forming front surface fields on the illuminated surface 203 for n-type back junction designs, then these implant steps are likewise activated.

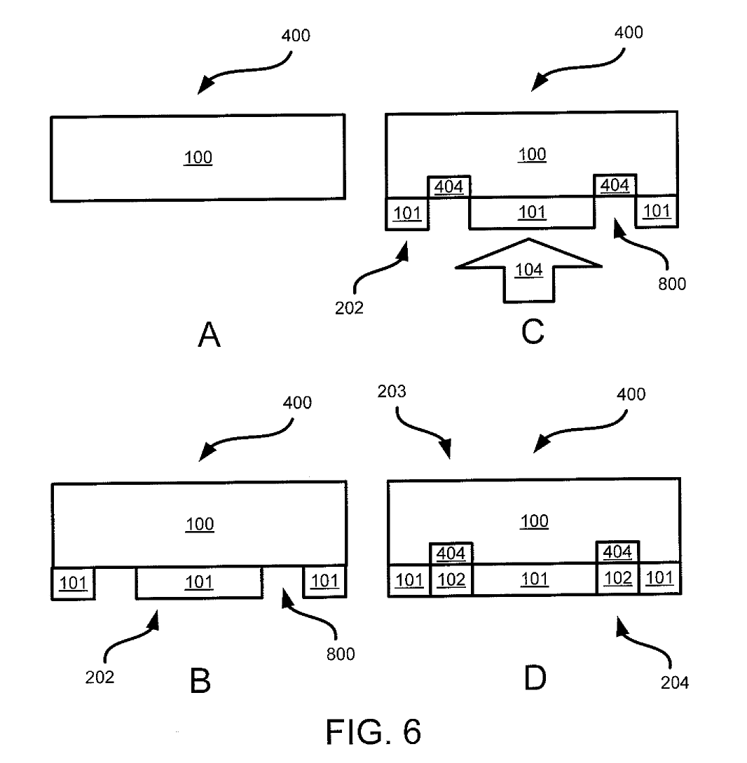

FIGS. 6A-D illustrate a third process of fabricating a solar cell. The substrate 100 of the solar cell 400 in FIG. 6A may be either n-type or p-type. In FIG. 6B, the aluminum layer 101 is formed on the non-illuminated surface 202. The aluminum layer 101 includes at least one hole 800. The aluminum layer 101 and hole 800 may be formed by screen printing, PVD, or sputter/evaporation followed by a drying step.

In FIG. 6C, a blanket ion implant of a p-type dopant 104 into the substrate 100 is performed. This implant covers the entire non-illuminated surface 202 of the solar cell 400. However, the aluminum layer 101 serves as a mask. Thus, the p-type dopant 104 is only implanted through the holes 800 in the aluminum layer 101 to form the p-type regions 404. These p-type regions 404 in the substrate 100 are only formed under these holes 800. In FIG. 6D, contacts 102 are disposed in the holes 800 on the non-illuminated surface 202 of the solar cell 400. The contacts 102 are primarily applied to the p-type regions 404 while the aluminum layer 101 is applied to the substrate 100. The contact surface 204 of each contact 102 is still exposed because the aluminum layer 101 does not cover the contacts 102. The p-type regions 404 and aluminum layer 101 are fired or activated either separately or at least partially simultaneously.

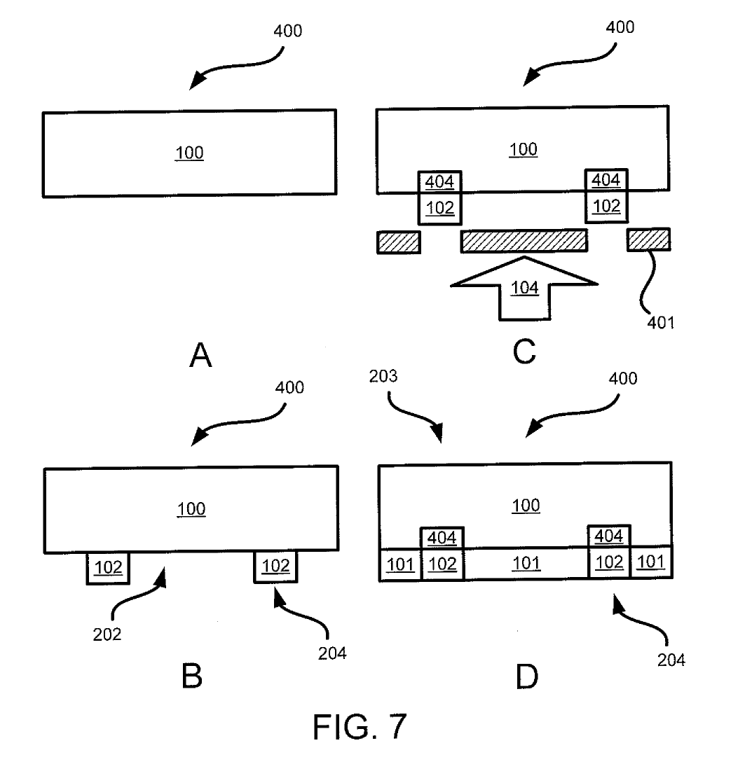

FIGS. 7A-D illustrate a fourth process of fabricating a solar cell. In this embodiment, the contacts 102 are applied primarily to the non-illuminated surface 202 in FIG. 7B. In FIG. 7C a selective implant of p-type dopant 104 is performed. The selective implant uses a mask 401 and forms the p-type regions 404 by implanting through the contacts 102. These p-type regions 404 are interrupted and do not cover the entire non-illuminated surface 202 of the substrate 100 in this embodiment. The mask 401 in FIG. 7C is aligned to predominantly implant into and through the contacts 102 and not elsewhere in the substrate 100. In FIG. 7D, an aluminum layer 101 is disposed on the non-illuminated surface 202 of the solar cell 400. The aluminum layer 101 may be formed by screen printing, PVD, or sputter/evaporation followed by a drying step. The aluminum layer 101 is primarily applied to the substrate 100 rather than the portion of the non-illuminated surface 202 that includes the p-type regions 404. The contact surface 204 of each contact 102 is still exposed because the aluminum layer 101 does not cover the contacts 102. Instead, the aluminum layer 101 fills in between the contacts 102.

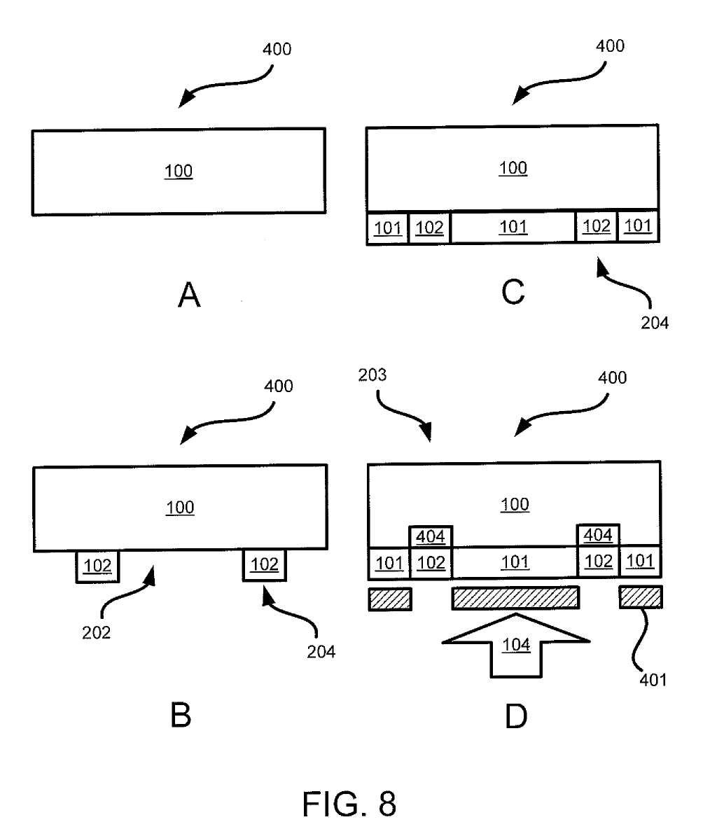

FIGS. 8A-D illustrate a fifth process of fabricating a solar cell. In this embodiment, the contacts 102 are applied primarily to the non-illuminated surface 202 in FIG. 8B. In FIG. 8C, an aluminum layer 101 is disposed on the non-illuminated surface 202 of the solar cell 400. The aluminum layer 101 may be formed by screen printing, PVD, or sputter/evaporation followed by a drying step. The contact surface 204 of each contact 102 is still exposed because the aluminum layer 101 does not cover the contacts 102. Instead, the aluminum layer 101 fills in between the contacts 102. In FIG. 8D a selective implant of p-type dopant 104 is performed. The selective implant uses a mask 401 and forms the p-type regions 404 by implanting through the contacts 102. These p-type regions 404 are interrupted and do not cover the entire non-illuminated surface 202 of the substrate 100. The mask 401 is aligned to predominantly implant into and through the contacts 102 and not elsewhere in the substrate 100. In an alternate embodiment, the aluminum layer 101 may serve as a mask due to its material properties or dimensions and no mask 401 is used. Thus, a blanket implant of the p-type dopant 104 is performed, but the implant into the substrate 100 only forms the p-type regions 404.

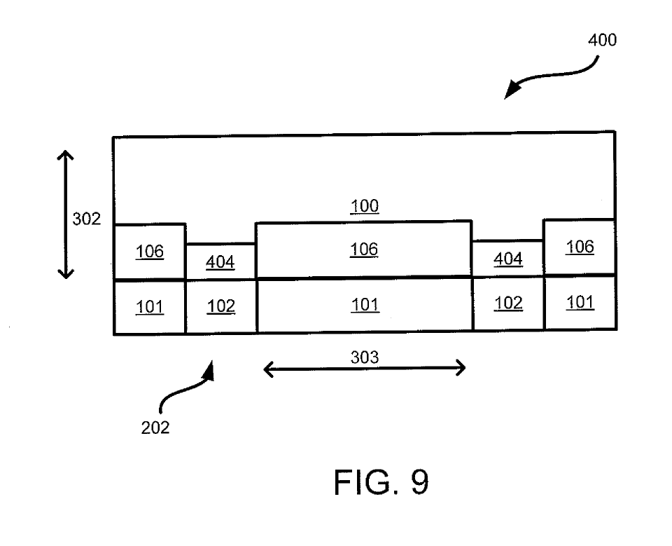

FIG. 9 is a cross-sectional view of a second embodiment of a solar cell with an aluminum eutectic. The solar cell 400 had a selective implant of p-type dopant 104 as illustrated in FIGS. 4B, 6C, 7C, and 8D. After activation, the p-type regions 404 under the contacts 102 may only be, for example, approximately 1 μm or less in thickness or height, which is represented by the direction 302 in FIG. 7. In contrast, the silicon-aluminum eutectic that occurs after firing of the aluminum layer 101 may be over approximately 5 μm in thickness or height in one instance. There may be a difference in height or thickness in the direction 302 between the p-type regions 404 and the second regions 106 of aluminum in this particular embodiment, but there may not be overlap between the p-type regions 404 and the second regions 106 in the direction 303. In other embodiments, the second regions 106 and p-type-regions 404 are the same height or thickness in the direction 302 or have some overlap in the direction 303.

If the substrate 100 in FIG. 2, 4, 6, 7, or 8 is p-type, then the p-type region 301 or p-type regions 404 form a p+ BSF. The p-type region 301 in FIG. 2B, p-type region 301 and first region 107 in FIG. 3, or the second regions 106 and p-type regions 404 in FIG. 9 may be across the entire non-illuminated surface 202, which improves performance of the solar cell 300 or solar cell 400. A continuous p+ BSF formed across the non-illuminated surface 202 reduces recombination.

Alternatively, if the substrate 100 in FIG. 2, 4, 6, 7, or 8 is n-type, the p-type region 301 or p-type regions 404 under the contacts 102 may create a p-n junction with the substrate 100. This isolates the contacts 102 from any front metal contact and prevents shunting, increases fill factor, and increases cell efficiency. Shunting is prevented in part because of the presence of the p-type region 301 or p-type regions 404, which serves as a blocking diode.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method to process a substrate comprising:
implanting a first surface of a p-type substrate with a p-type dopant thereby forming a p-type region;
forming a plurality of contacts on said first surface of said p-type substrate, each of said plurality of contacts having a contact surface opposite said first surface of said p-type substrate;
forming an aluminum layer on said first surface of said p-type substrate, said aluminum layer disposed around said plurality of contacts such that said contact surface of each of said plurality of contacts is exposed; and
wherein said plurality of contacts is disposed on said p-type region.

2. The method of claim 1, wherein said first surface is entirely covered by said contacts and said aluminum layer.

3. The method of claim 1, wherein said p-type substrate is a solar cell and said first surface is a non-illuminated side of said solar cell.

4. The method of claim 1, wherein said implanting said first surface is a selective implant.

5. The method of claim 4, wherein said selective implant uses a mask.

6. The method of claim 1, wherein said p-type dopant is selected from the group consisting of boron, aluminum, gallium, and indium.

7. The method of claim 1, wherein said implanting said first surface is across the entirety of said first surface.

8. The method of claim 1, wherein said forming said aluminum layer occurs before said implanting said first surface.

9. The method of claim 1, wherein said forming said plurality of contacts occurs before said implanting said first surface and wherein said implanting said first surface is through said plurality of contacts.

10. A method to process a substrate comprising:
implanting a p-type dopant into a first surface of an n-type substrate thereby forming a p-type emitter;
forming a plurality of contacts on said first surface of said n-type substrate, each of said plurality of contacts having a contact surface opposite said first surface of said n-type substrate;
forming an aluminum layer on said first surface of said n-type substrate, said aluminum layer disposed around said plurality of contacts such that said contact surface of each of said plurality of contacts is exposed; and
wherein said plurality of contacts is disposed on said p-type emitter.

11. The method of claim 10, wherein said p-type dopant is selected from the group consisting of boron, aluminum, gallium, and indium.

12. The method of claim 10, wherein said n-type substrate is a solar cell and said first surface is a non-illuminated side of said solar cell.

13. The method of claim 10, wherein said implanting said p-type dopant is a selective implant.

14. The method of claim 13, wherein said selective implant uses a mask.

15. The method of claim 10, wherein said implanting said p-type dopant is across the entirety of said first surface.

16. The method of claim 10, wherein said forming said aluminum layer occurs before said implanting said p-type dopant.

17. The method of claim 10, wherein said forming said plurality of contacts occurs before said implanting said p-type dopant and wherein said implanting said p-type dopant is through said plurality of contacts.

18. A solar cell comprising:
a substrate having an illuminated surface and a non-illuminated surface, wherein light impinges said illuminated surface;
a p-type region in said substrate proximate said non-illuminated surface;
a plurality of contacts disposed on said non-illuminated surface of said substrate, each of said plurality of contacts having a first surface and a second surface, said second surface being disposed on said p-type region of said substrate; and
an aluminum layer disposed on said non-illuminated surface of said substrate, said aluminum layer disposed around said plurality of contacts such that said first surface of each of said plurality of contacts is exposed.

19. The solar cell of claim 18, wherein said substrate is p-type and wherein said p-type region comprises a back surface field.

20. The solar cell of claim 18, wherein said substrate is n-type and wherein said p-type region comprises an emitter.

21. The solar cell of claim 18, wherein said p-type region is formed using a dopant selected from the group consisting of boron, aluminum, gallium, and indium.

22. The solar cell of claim 18, wherein said p-type region comprises a plurality of p-type sections, wherein each of said plurality of contacts is disposed on one of said plurality of p-type sections.

23. The solar cell of claim 22, further comprising a eutectic layer in said substrate, said eutectic layer adjacent said aluminum layer and said eutectic layer comprising aluminum and silicon, wherein said eutectic layer is disposed on said aluminum layer between said plurality of p-type sections.

24. The solar cell of claim 23, wherein said eutectic layer and said p-type regions are uninterrupted across said non-illuminated surface.
